(19) United States
(12) Patent Application Publication
(10) Pub. No.: US 2026/0123056 A1
(43) Pub. Date: Apr. 30, 2026

(54) SEMICONDUCTOR DEVICE

(71) Applicant: Sanken Electric Co., Ltd., Saitama-ken (JP)

(72) Inventors: Naoto Fujita, Saitama-ken (JP); Hideyuki Kubota, Saitama-ken (JP); Mamoru Sato, Saitama-ken (JP)

(73) Assignee: Sanken Electric Co., Ltd., Saitama-ken (JP)

(21) Appl. No.: 19/290,363

(22) Filed: Aug. 5, 2025

(30) Foreign Application Priority Data
Oct. 24, 2024 (JP) 2024-187077

(51) Int. Cl. H10D 89/60; H10D 8/00; H10D 10/60; H10D 30/60; H10D 30/65; H10D 62/10; H10D 64/00; H10D 84/00

(52) U.S. Cl. CPC H10D 89/611; H10D 8/411; H10D 10/60; H10D 30/611; H10D 30/655; H10D 62/103; H10D 62/126; H10D 64/112; H10D 84/151; H10D 84/153; H10D 89/711; H10D 89/811

(57) ABSTRACT

The semiconductor device includes an n-type first semiconductor region 11, and an n-type common contact region 12 formed locally with a high impurity concentration on the first semiconductor region 11 and connected to a common electrode that serves as both a first main electrode of a switching element and a protection element side first electrode on the protection element side. A p-type second semiconductor region 13 and an n-type third semiconductor region 14 are provided in a switching element region R1. The p-type second semiconductor region 13 is formed in the first semiconductor region 11 at a location separated in the radial direction from the common contact region 12, and the n-type third semiconductor region 14 is formed in the second semiconductor region 13. A second main electrode is connected to the third semiconductor region 14. A p-type fourth semiconductor region 16 is provided in a protection element region R2. The p-type fourth semiconductor region 16 is formed in the first semiconductor region 11 at a location separated in the radial direction from the common contact region 12. A protection element side second electrode is connected to the fourth semiconductor region 16.

### CROSS-REFERENCE TO RELATED APPLICATION

This application claims the priority benefit of Japanese application serial no. 2024-187077, filed on Oct. 24, 2024. The entirety of the above-mentioned patent application is hereby incorporated by reference herein and made a part of this specification.

### TECHNICAL FIELD

The disclosure relates to a semiconductor device in which a lateral switching element and a protection element thereof are combined.

### BACKGROUND

A lateral LDMOS (laterally diffused MOS) transistor (switching element) having a drift layer, through which an on current flows, in the plane direction of a semiconductor layer is preferably used as a power semiconductor element to achieve a high breakdown voltage. In this case, the length along the electric field direction of a region (high breakdown voltage region) where the electric field strength becomes particularly high during the off state and therefore the breakdown voltage should be secured is set in the in-plane direction of the semiconductor layer so as to secure the breakdown voltage.

Furthermore, as described in Patent Document 1 (Japanese Patent Application Laid-Open No. 2006-319072), for example, a technique is used in this LDMOS in which a protection element (for example, a diode) is connected between the source and drain of the LDMOS, and in the case where a surge voltage exceeding the breakdown voltage is applied to the LDMOS, this protection element breaks down instead of the LDMOS to bypass the current, thereby preventing damage to the LDMOS and electric circuits connected thereto.

In this case, the breakdown voltage of this protection element (diode) is set high corresponding to the LDMOS. Therefore, this diode is also lateral, and the high breakdown voltage region is set with a certain size in the diode as well, similar to the LDMOS. In the technique described in Patent Document 1, the LDMOS is formed in one region on a plane, and the region constituting the diode is formed surrounding this LDMOS.

As described above, in order to form both the LDMOS and the lateral protection element on a common semiconductor substrate and to increase the breakdown voltage of both, a large area is required for the total of both regions. Alternatively, in the case of a limited area, the current flowing through the LDMOS or the protection element cannot be increased, resulting in a reduction in the protection function. Therefore, it has been difficult to obtain a compact semiconductor device with a high breakdown voltage in which a switching element and a protection element that protects the switching element are combined.

The disclosure provides a semiconductor device that solves the above problems.

### SUMMARY

The disclosure has the following configuration to solve the above problems.

The semiconductor device of the disclosure is a semiconductor device, in which a switching element whose on/off is controlled by a potential of a control electrode between a first main electrode on a high potential side and a second main electrode on a low potential side, and a protection element that bypasses and flows a current between a protection element side first electrode on the high potential side and a protection element side second electrode on the low potential side during an off state of the switching element are formed on a semiconductor substrate. The semiconductor device includes: a first semiconductor region of a second conductivity type formed on a surface side of the semiconductor substrate of a first conductivity type, in which the second conductivity type is opposite to the first conductivity type; a common electrode serving as both the first main electrode and the protection element side first electrode; and a common contact region of the second conductivity type formed locally with a high impurity concentration on the first semiconductor region and connected to the common electrode. One region and another region in a circumferential direction centered on the common contact region in plan view are respectively set as a switching element region where the switching element is formed and a protection element region where the protection element is formed. The switching element region includes a second semiconductor region of the first conductivity type and a third semiconductor region of the second conductivity type, in which the second semiconductor region of the first conductivity type is locally formed at a location separated in a radial direction in the first semiconductor region from the common contact region in plan view, and the third semiconductor region of the second conductivity type is locally formed in the second semiconductor region in plan view. The second main electrode is connected to the third semiconductor region. The protection element region includes a fourth semiconductor region of the first conductivity type, in which the fourth semiconductor region of the first conductivity type is locally formed at a location separated in the radial direction in the first semiconductor region from the common contact region in plan view. The protection element side second electrode is connected to the fourth semiconductor region. The first semiconductor region is integrated across the switching element region and the protection element region, and an end portion of the second semiconductor region on the common contact region side and an end portion of the fourth semiconductor region on the common contact region side are separated from each other in plan view.

A shortest distance from the common contact region to the fourth semiconductor region in the protection element region may be set shorter than a shortest distance from the common contact region to the second semiconductor region in the switching element region.

The semiconductor device may include a buried semiconductor region of the second conductivity type formed deeper than the first semiconductor region on the common contact region side in the semiconductor substrate and connected to the first semiconductor region, in which a shortest distance from the common contact region to the second semiconductor region and a shortest distance from the common contact region to the fourth semiconductor region are set equal, and a shortest distance from the buried semiconductor region to the second semiconductor region in the switching element region is set shorter than a shortest distance from the buried semiconductor region to the fourth semiconductor region in the protection element region.

A plurality of field plates composed of conductors and facing a surface of the first semiconductor region through an insulating layer may be formed to surround the common electrode in plan view so as to be capacitively coupled to each other between the common electrode and the control electrode, and between the common electrode and the protection element side second electrode.

The semiconductor device may include a fifth semiconductor region of the second conductivity type locally formed in the fourth semiconductor region, in which the protection element side second electrode is connected to the fifth semiconductor region.

A shortest distance from the common contact region to the second semiconductor region in the switching element region and a shortest distance from the common contact region to the fourth semiconductor region in the protection element region may be set equal.

One of the second semiconductor region and the fourth semiconductor region may be formed inside the first semiconductor region in plan view.

One of the second semiconductor region and the fourth semiconductor region in plan view may be connected to the semiconductor substrate on an outer side in the radial direction.

The second semiconductor region may be formed inside the first semiconductor region in plan view, and a distance between an outermost periphery in the radial direction of a side that is not in direct contact with the semiconductor substrate other than a portion where the first semiconductor region is formed, and an outermost periphery in the radial direction of the first semiconductor region may be set to a length equal to or less than a distance between the second semiconductor region and the fourth semiconductor region in the circumferential direction.

An inter-element field plate composed of a conductor may be formed on a surface of the first semiconductor region through an insulating layer, on the surface of the first semiconductor region between the second semiconductor region and the fourth semiconductor region where the second semiconductor region and the fourth semiconductor region are locally separated in the circumferential direction in plan view.

The inter-element field plate may be connected to the second semiconductor region, the fourth semiconductor region, or the control electrode by a conductive material.

Since the disclosure is configured as described above, it is possible to obtain a compact semiconductor device with a high breakdown voltage in which a switching element and a protection element that protects the switching element are combined.

### BRIEF DESCRIPTION OF THE DRAWINGS

FIG. 1 is a circuit diagram showing the configuration of the semiconductor device according to an embodiment of the disclosure.

FIG. 2 is a cross-sectional view of the switching element region side of the semiconductor device according to an embodiment of the disclosure.

FIG. 3 is a cross-sectional view of the protection element region side of the semiconductor device according to an embodiment of the disclosure.

FIG. 4 is a top view showing the configuration (excluding the field plate) of the semiconductor device according to an embodiment of the disclosure.

FIG. 5 is a cross-sectional view of an example in which the depth directional profiles of the second semiconductor region and the fourth semiconductor region differ in the semiconductor device according to an embodiment of the disclosure.

FIG. 6 is a cross-sectional view of an example in which the structure of the first semiconductor region differs in the semiconductor device according to an embodiment of the disclosure.

FIG. 7A is a top view showing the configuration of the field plate in the semiconductor device according to an embodiment of the disclosure, and FIG. 7B is a partially enlarged view thereof.

FIG. 8 is a circuit diagram showing the configuration of the first modification example of the semiconductor device according to an embodiment of the disclosure.

FIG. 9 is a cross-sectional view of the protection element region side of the first modification example of the semiconductor device according to an embodiment of the disclosure.

FIG. 10A and FIG. 10B are top views in the case of two types of positional relationships among the first semiconductor region, the second semiconductor region, and the fourth semiconductor region in the semiconductor device according to an embodiment of the disclosure.

FIG. 11A to FIG. 11D are top views in the case of four types of positional relationships among the first semiconductor region, the second semiconductor region, and the fourth semiconductor region in the first modification example of the semiconductor device according to an embodiment of the disclosure.

FIG. 12 is a view showing the setting of distances between respective layers in the case of making the potentials of the second semiconductor region and the fourth semiconductor region differ in the semiconductor device according to an embodiment of the disclosure.

FIG. 13 is a top view of an example of the structure in which the protection element more easily breaks down than the switching element in the semiconductor device according to an embodiment of the disclosure.

FIG. 14 is a top view partially showing the configuration of the second modification example of the semiconductor device according to an embodiment of the disclosure.

FIG. 15 is a partial cross-sectional view of the second modification example of the semiconductor device according to an embodiment of the disclosure.

FIG. 16 is a plan view of the configuration of another example (No. 1) of the inter-element field plate in the second modification example of the semiconductor device according to an embodiment of the disclosure.

FIG. 17 is a plan view of the configuration of another example (No. 2) of the inter-element field plate in the second modification example of the semiconductor device according to an embodiment of the disclosure.

FIG. 18 is a circuit diagram showing the configuration of the third modification example of the semiconductor device according to an embodiment of the disclosure.

### DESCRIPTION OF THE EMBODIMENTS

Hereinafter, a semiconductor device according to an embodiment of the disclosure will be described. In the following description of the figures, identical or similar parts are denoted by identical or similar reference numerals. However, it should be noted that the figures are schematic, and the relationship between thickness and planar dimensions, the ratio of length of each part, etc., may differ from actual ones. Therefore, specific dimensions should be determined with reference to the following description. Also, it is needless to say that portions having different dimensional relationships and ratios are included between the figures. Further, the embodiments shown below exemplify devices for embodying the technical concept of the disclosure, and the technical concept of the disclosure does not specify the shape, structure, arrangement, etc. of the components to those described below. The embodiments of the disclosure can be modified in various ways within the scope of the claims. In the disclosure, terms specifying up and down such as “upper” and “lower” are used to facilitate the description, and components that are substantially identical to the components of the disclosure belong to the scope of rights of the disclosure even if they are provided on a side surface. In addition, “on” includes not only the case where an object is formed in contact with another object, but also the case where there is a layer therebetween. Further, in the disclosure, “connection” is not limited to direct connection, and components that are substantially identical to the components of the disclosure belong to the scope of rights of the disclosure even if they are connected with a resistor or the like therebetween.

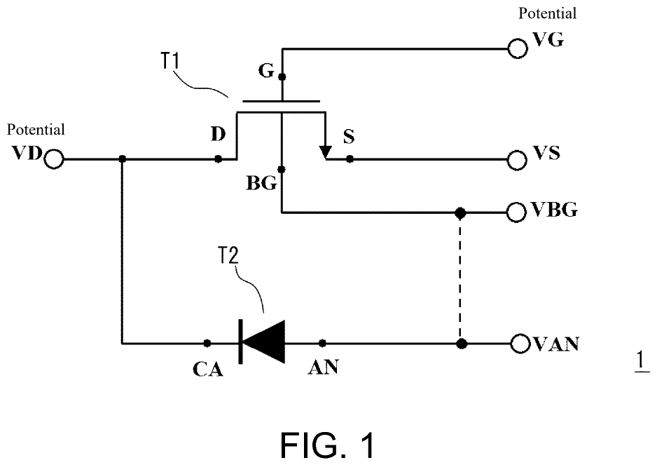

FIG. 1 is a circuit diagram showing the configuration of this semiconductor device 1. Here, an element (switching element) T1 which is an n-channel type MOSFET (LDMOS) as a switching element, and an element (protection element) T2 which is a diode (pn diode) are formed on a common semiconductor substrate. Here, an n-type layer (drift layer) connected to a drain (D: high potential side electrode (first main electrode)) in the element T1 and an n-type layer connected to a cathode (CA) in the element T2 are common. A source (S: low potential side electrode (second main electrode)), a gate (G: first control electrode), and structures related to these are the same as those of a normal MOSFET, and a potential VS of the source (S) is, for example, a ground potential (GND), and in the case where a potential VD of the drain (D) is a positive potential, on/off of the current between the drain (D) and the source (S) is controlled by a voltage VG of the gate (G).

At this time, a potential VBG of a body layer (BG) of the element T1 (MOSFET) may be set equal to the source (S), but may also be controlled independently of VS by applying a predetermined potential to a back gate electrode (second control electrode). This makes it possible to adjust the characteristics of the element T1.

In addition, the element T2 is a pn-type diode, and the cathode (CA: protection element side first electrode) thereof is common with the drain (D: first main electrode) of the element T1, so the aforementioned VD is applied. Also, the potential of an anode (AN: protection element side second electrode) thereof is VAN which is close to the ground potential, similar to VBG. In the potential setting of VD and VAN as described above, the element T2 is normally off (reverse bias), but in the case where VD becomes large, the element T2 breaks down and enables a large current to flow. This characteristic can be finely adjusted by VAN, etc.

In the case where a positive voltage such as a high voltage surge is applied to the drain (D) side during the off state of the element T1, the element T1 may break down. At this time, in the case where the element T2 breaks down before the breakdown of the element T1 (bypassing and flowing the current on the element T2 side), the flow of a large current due to breakdown on the element T1 side is suppressed, making it possible to prevent causing damage to the element T1 or electric circuits connected thereto.

VBG in the element T1 and VAN in the element T2 may be common (broken line in the figure) or may be controlled individually, and this is easily realized by wiring connection. In addition, as described later, it is possible to realize a structure in which either VBG or VAN in FIG. 1 automatically becomes GND.

Here, the region on the plane in the semiconductor layer where electric field strength becomes high during the off state of the semiconductor device 1 on the element T1 side is the region between the gate (G) and the drain (D) where the potential difference at both ends becomes particularly large, and the region where electric field strength becomes high during the off state of the semiconductor device 1 on the element T2 side is the region between the cathode (CA) and the anode (AN). Therefore, in order to realize a high breakdown voltage, it is necessary to make each of these regions wide along the electric field direction. In FIG. 1, the drain (D) of the element T1 and the cathode (CA) of the element T2 are connected to a common terminal whose potential is VD, and in addition, in this semiconductor device 1, a substantially circular region in the semiconductor substrate is divided in the circumferential direction and partitioned into a portion that operates as the element T1 and a portion that operates as the element T2. Thereby, the entire semiconductor device 1 can be miniaturized even in the case of setting the breakdown voltage of the element T1 and the element T2 high.

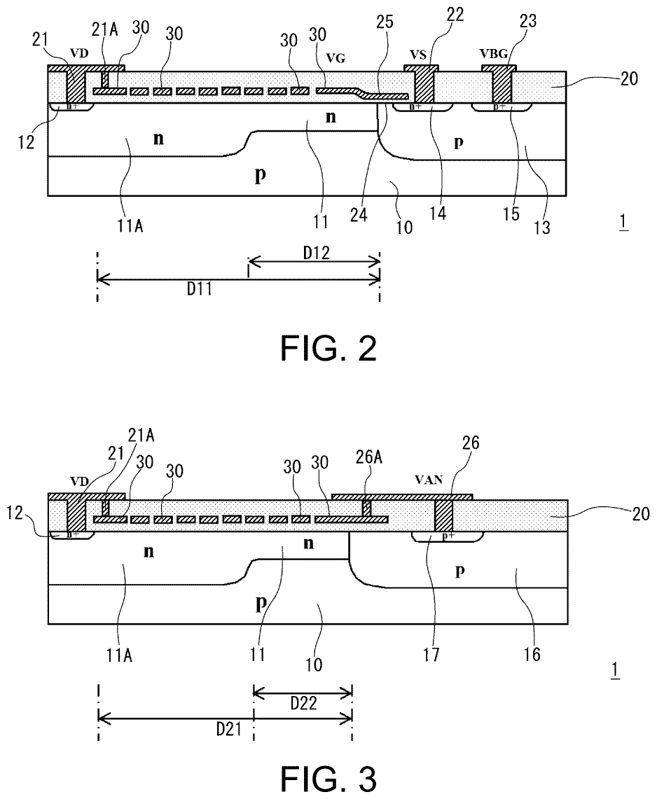

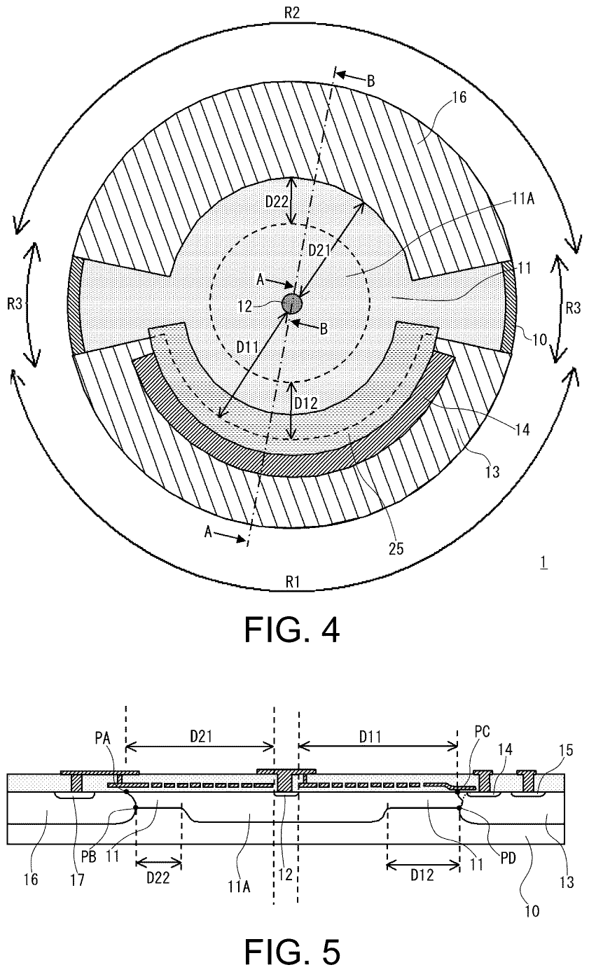

FIG. 2 is a cross-sectional view of a region (switching element region) where the element T1 is formed in this semiconductor device 1, FIG. 3 is a cross-sectional view of a region (protection element region) where the element T2 is formed, and FIG. 4 is a top view of this semiconductor device 1. FIG. 2 is a cross-sectional view in the A-A direction in FIG. 4, and FIG. 3 is a cross-sectional view in the B-B direction. In FIG. 2 and FIG. 3, this semiconductor device 1 is formed on a p-type substrate (semiconductor substrate) 10 that is p-type (first conductivity type). In FIG. 4, R1 is a switching element region, R2 is a protection element region, and R3 is a connection region that connects between these.

In FIG. 2 and FIG. 3, an n layer (first semiconductor region) 11 that is n-type (second conductivity type) is formed widely in the illustrated shape on the surface side of the p-type substrate 10, and both the element T1 and the element T2 in FIG. 1 are formed using this n layer 11. In FIG. 2 and FIG. 3, the right side of the n layer 11 is the low potential side (side close to ground potential), and the left side is the high potential (for example, +600V or higher) side. In FIG. 2 (switching element region), on the low potential side (right side in the figure), a p-type p layer (second semiconductor region) 13 that serves as a body region of the MOSFET is formed, and on the higher potential side than this, the n-type n layer (first semiconductor region) 11 is formed. Further, on the high potential side of the n layer 11, a deeper n-type n layer (buried n-type layer: buried semiconductor region) 11A is formed with a high concentration and connected to the n layer 11. Similarly, in FIG. 3 (protection element region), on the low potential side (right side in the figure), a p layer 16 is formed corresponding to the aforementioned p layer 13, but the impurity concentration, depth, etc. thereof are not necessarily identical to the p layer 13. On the higher potential side than this, similar to FIG. 2, an n layer 11 and an n layer (buried n-type layer: buried semiconductor region) 11A are similarly formed. As described later, the n layer 11 and the n layer 11A in the switching element region (FIG. 2) are respectively connected to the n layer 11 and the n layer 11A in the protection element region side (FIG. 3), but the impurity concentration and depth thereof do not necessarily match between the switching element region side and the protection element region side, and can be individually adjusted according to the characteristics of the element T1 and the element T2.

In FIG. 4, the overall shape of the n layer 11A is circular (that is, the same sector shape on the switching element R1 side and the protection element region R2 side), but this shape is not necessarily circular (the shapes on the switching element R1 side and the protection element region R2 side are not necessarily identical). That is to say, this shape can be appropriately set according to the characteristics of the LDMOS and the characteristics of the diode. The same applies not only to the shape but also to the impurity concentration. Furthermore, regarding impurity concentration, the same applies to the n layer 11 as well.

Additionally, in FIG. 2 and FIG. 3, on the surface of the left side (high potential side) of the n layer 11, an n⁺ layer (common contact region) 12 which is a high concentration n-type layer is formed. As shown in FIG. 4, the n⁺ layers 12 in these figures are actually the same, and FIG. 2 and FIG. 3 show the cross-sections in different directions.

In FIG. 2, the n⁺ layer 12 on the n layer 11 functions as a contact layer in the drain (D) region of the element T1 in FIG. 1. On the other hand, on the surface of the p layer 13, an n⁺ layer (third semiconductor region) 14 which is high concentration n-type, and a p⁺ layer 15 which is high concentration p-type are formed on the left side and right side, respectively. The p⁺ layer 15 is formed as a contact layer to the player 13 (second semiconductor region), whereby the potential of the p layer 13 is set to VBG in FIG. 1. The n⁺ layer 14 functions as the source (S) region of the element T1, and the potential thereof is set to VS in FIG. 1.

In FIG. 3, the n⁺ layer 12 on the n layer 11 functions as a contact layer in the cathode (CA) region of the element T2 in FIG. 1. That is, the n⁺ layer 12 becomes a common contact region for connecting to the drain (D) and the cathode (CA) in FIG. 1. On the surface of the p-type substrate 10 on the right side (low potential side) in FIG. 3, a p-type p layer (fourth semiconductor region) 16 that is in contact with the n layer 11 is formed corresponding to the p layer 13 in FIG. 2. As described later, the p layer 13 and the p layer 16 are actually separated in terms of element operation, but in FIG. 2 and FIG. 3, both of these have potentials that directly contact the p-type substrate 10, so VBG=VAN(=VS) in FIG. 1. Here, the potential of the p-type substrate 10 can be, for example, GND.

On the surface of the player 16, a p⁺ layer 17 which is p-type with a higher concentration than the p layer 16 is formed. The p layer 16 functions as an anode layer of the element T2, and the potential thereof is set to VAN in FIG. 1. The p⁺ layer 17 is formed for contact to the p layer 16 which becomes the anode layer.

In FIG. 2 and FIG. 3, an interlayer insulating layer 20 composed of a silicon oxide film is formed on the semiconductor substrate on which the above structure is formed, and each wiring is connected to each of the above layers through openings formed in the interlayer insulating layer 20 to realize the circuit configuration of FIG. 1. First, a drain electrode (common electrode) 21 of the element T1 is connected to the n⁺ layer 12. As described above, the drain electrode 21 whose potential is set to VD in the figure also serves as the collector electrode of the element T2. In FIG. 2, a source electrode (second main electrode) 22 whose potential is set to VS is connected to the n⁺ layer 14, and on the right side thereof in the figure, a back gate electrode (second control electrode) 23 whose potential is set to VBG is connected to the p⁺ layer 15. As described above, in this semiconductor device 1, VS, VBG, and VAN in FIG. 1 are controlled independently.

In addition, on the surface of the p layer 13 from the n⁺ layer 14 to the location where the n layer 11 is exposed on the left side surface thereof, a gate electrode (first control electrode) 25 whose potential is set to VG in FIG. 1 is formed to face the p layer 13 through a gate oxide film 24 that is thinner than the interlayer insulating layer 20. With this structure, the element T1 which is a MOSFET that operates using the drain electrode 21, the source electrode 22, and the gate electrode 25 (and further the back gate electrode 23) is formed. In this MOSFET, in the case where an on current flows through the n layer 11 from the p layer 13 to the n⁺ layer 12 during the on state, and a high voltage is applied to the drain electrode 21 during the off state, at least a part of the n layer 11 in this region is depleted.

Further, in FIG. 2, a silicon oxide film thicker than the gate oxide film 24 is formed directly below the portion on the left side of the gate electrode 25. This portion functions as a field plate 30 which will be described later.

On the other hand, in FIG. 3, an anode electrode (protection element side second electrode) 26 whose potential is set to VAN is connected to the p⁺ layer 17. Thereby, the element T2 in FIG. 1 is formed. During normal use, in the element T2, VAN is set to a potential close to ground potential, and the drain electrode 21 side serving as a cathode electrode becomes VD which is a high potential as described above, so the element T2 is in the off state. Therefore, the influence that the element T2 exerts on the operation of the element T1 is small.

Also, the anode electrode 26 is connected on the left side thereof to a field plate (field plate 30 which will be described later) that faces the n layer 11A through a silicon oxide film thicker than the gate oxide film 24.

In FIG. 2, the n layer 11 between the p layer 13 and the n⁺ layer 12 on the surface side becomes a region where the breakdown voltage should be secured (breakdown voltage securing region) because electric field strength in a depletion layer formed during the off state of the element T1 increases. Here, in order to secure the breakdown voltage, multiple field plates 30 are arranged along the left-right direction in the figure (direction in which an electric field distribution is generated during use) on the surface of the n layer 11 and the n layer 11A between the p layer 13 and the n′ layer 12, through a silicon oxide film thicker than the gate oxide film 24. Although a cross section is shown in FIG. 2, as described later, each field plate 30 is formed to concentrically surround the n⁺ layer 12 or the drain electrode 21, whereby the surface potential of the n layer 11 directly below each field plate 30 is made uniform, and this surface potential is appropriately distributed from the field plate 30 on the highest potential side (left side in the figure) to the field plate 30 on the lowest potential side (right side in the figure) in FIG. 2 such that regions with locally high electric field strength are not formed by capacitive coupling between adjacent field plates 30. The action of such field plates 30 is as described in, for example, Japanese Patent No. 3275964. That is, this structure can increase the breakdown voltage in the breakdown voltage securing region.

In FIG. 3, the n layer 11 between the p layer 16 and the n⁺ layer 12 on the surface side also becomes a region where the breakdown voltage should be secured (breakdown voltage securing region) because electric field strength in a depletion layer formed in the element T2 increases during the off state of the element T1. Here, field plates 30 are arranged in the same manner as described above, and the action thereof is also the same as described above. The planar structure of the field plates 30 in FIG. 2 and FIG. 3 and the electrical connection thereof will be described later.

Since the thick silicon oxide film in the region where the field plates 30 are actually formed is formed as, for example, a LOCOS oxide film, the surface of the semiconductor layer (n layer 11, etc.) in this region is actually positioned below the surface of the p layer 13, etc. directly below the gate electrode 25, and these surfaces are not on the same plane. In FIG. 2, the surfaces of the semiconductor layers are described in a simplified manner as constituting the same plane. The same applies to the cross-sectional views described hereinafter.

Among the components shown in FIG. 2 and FIG. 3, only the structures in the semiconductor layer, which are the p-type substrate 10, the n layer 11, the n layer 11A, the n⁺ layer 12, the p layer 13, the p layer 16, the n⁺ layer 14, and the gate electrode 25 are shown in the top view of FIG. 4. Here, only the region of the circular semiconductor device 1 centered on the n⁺ layer 12 is extracted, and different semiconductor devices may be provided on the p-type substrate 10 on the outer side thereof. The player 13, the n⁺ layer 14, and the gate electrode 25 constituting the element T1 are formed only in the switching element region R1 on the lower side in the figure, and the p layer 16 constituting the element T2 is formed only in the protection element region R2 on the upper side in the figure. At this time, the n layer 11 is continuously formed from the lower half (switching element region R1) through the connection region R3 to the upper half (protection element region R2), but with the connection region R3 as a boundary, the p layer 13 is formed and divided in the lower half (switching element region R1) in the figure, and the p layer 16 is formed and divided in the upper half (protection element region R2) in the figure. Here, the n layer 11A has a circular shape centered on the n⁺ layer 12, that is, the n layer 11A has the same planar shape and size on the switching element region R1 and the protection element region R2 sides, but as described above, the n layer 11A can actually be set individually on the switching element region R1 side and the protection element region R2 side, and the planar shape of the n layer 11A is not necessarily circular.

Further, in the element T1, the current flowing through the n layer 11 flows from the n⁺ layer 12 through the lower region R1 in FIG. 4, whereas in the element T2, the current flowing through the n layer 11 flows from the n⁺ layer 12 through the upper region R2 in FIG. 4. Therefore, by commonly applying VD of the drain (D) of the element T1 and the cathode (CA) of the element T2 in FIG. 1 to the n′ layer 12, the element T1 and the element T2 can be operated independently and individually, and the circuit of FIG. 1 can be realized. At this time, the circular center side in FIG. 4 becomes the high potential side, and the circular peripheral side becomes the low potential side.

Here, in the case where a surge voltage is mixed into VD during the off state and becomes excessive, in order to protect the element T1 with the element T2 in FIG. 1, it is necessary to cause breakdown to occur in the element T2 before breakdown occurs in the n layer 11 in the element T1. For this purpose, it is effective to set D11>D21, where D11 is the shortest distance between the n⁺ layer 12 and the p layer 13 on the element T1 side in FIG. 2 and FIG. 4, and D21 is the shortest distance between the n⁺ layer 12 and the p layer 16 on the element T2 side in FIG. 3 and FIG. 4.

Alternatively, it is effective to set D12<D22, where D12 is the shortest distance between the n layer 11A and the p layer 13 on the element T1 side in FIG. 2 and FIG. 4, and D22 is the shortest distance between the n layer 11A and the p layer 16 on the element T2 side in FIG. 3 and FIG. 4, in the case of D11⇄D21. In addition, it is effective to set D12>D22 in the case of D11−D12⇄D21−D22. Alternatively, by setting the impurity concentration of the n layer 11A in FIG. 2 (switching element region) lower than the impurity concentration of the n layer 11A in FIG. 3 (protection element region), the element T2 can similarly be broken down at a lower voltage than the element T1. That is to say, the breakdown voltages of the element T1 and the element T2 can be finely adjusted by these settings. Also, in FIG. 3, for example, in the case where D21 is kept constant, increasing D21−D22 raises the breakdown voltage of the element T2, and decreasing this lowers the breakdown voltage. In the case where D21−D22 is kept constant and D22 is decreased (extending the p layer 16 to the left side in FIG. 3), the breakdown voltage becomes smaller. Increasing the impurity concentration of the n layer 11A also decreases the breakdown voltage of the element T2. In this way, the breakdown voltage of the element T2 can be adjusted as appropriate.

The setting of the above distances (D11, etc.) can be made accordingly in the case where there is a depth (distance from the surface) at which breakdown particularly tends to occur in the element T1 and the element T2. In particular, depending on the formation method of the p layer 13 and the p layer 16 (combination of impurity diffusion and ion implantation), the depth directional profiles of the player 13 and the p layer 16 may not have a simple shape as shown in FIG. 2 and FIG. 3, and such a situation occurs in such cases. FIG. 5 is a cross-sectional view of the structure in which the element T1 side and the element T2 side are combined in the case where the depth directional profiles of the p layer 13 and the p layer 16 differ from FIG. 2 and FIG. 3. In FIG. 5, the n⁺ layer 12 is positioned at the center, the right half corresponds to the cross section of the switching element region R1 of FIG. 2, the left half corresponds to the cross section of the protection element region R2 of FIG. 3, and corresponds to the vertical cross section passing through the center of FIG. 4.

In this structure, the player 16 on the left side has a shape that extends toward the n layer 11A side below the surface. The p layer 13 on the right side has a shape in which a new shallow p layer is added on the surface side to a similar shape (dotted line in the p layer 13 in the figure), so that the surface side in this structure locally extends toward the center side (n⁺ layer 12 side), and the depth directional profile differs greatly between the p layer 16 and the p layer 13. Specifically, in the p layer 16 on the left side, a point PB, which is the end portion in the interior (the end portion that protrudes most toward the n⁺ layer 12 side), is separated in the horizontal direction from a point PA, which is the end portion at the surface. On the other hand, in the p layer 13 on the right side, the horizontal distance between a point PC, which is the end portion at the surface, and a point PD, which is the end portion in the interior (the end portion that protrudes most toward the n⁺ layer 12 side), is smaller than the distance between PA and PB.

The spacings D11, D21, D12, and D22 in the planar shape are shown in FIG. 4, but particularly in the case of the structure of FIG. 5, it is preferable to set D12 and D22 based on the points PB and PD in the interior rather than at the surface, as illustrated in the figure. That is, by setting the shortest distance from the point PD in the p layer 13 to the n layer 11A as D12 and the shortest distance from the point PB in the player 16 to the n layer 11A as D22, similar to the above, it is effective to set D12<D22 in the case of D11⇄D21, and to set D12>D22 in the case of D11−D12⇄D21−D22.

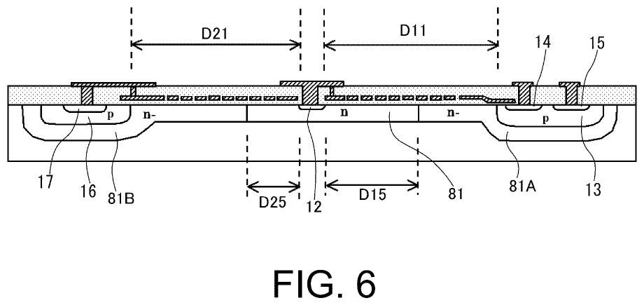

Furthermore, FIG. 6 shows a view corresponding to FIG. 5 in the case where the structure of the n layer (first semiconductor region) differs from FIG. 2 and FIG. 3. In this case, an n layer (first semiconductor region) 81 is formed on the n⁺ layer 12 side, and an n layer 81A and an n layer 81B having a lower impurity concentration than the n layer 81 are formed on the p layer 13 side and the p layer 16 side, respectively. Since the n layer 81A in this case is formed to the outer side of the p layer 13 and the p layer 16, the p layer 13 and the player 16 are not directly in contact with the p-type substrate 10. Therefore, VBG and VAN in FIG. 1 can be independently set. In this case, the aforementioned D11, D21, D15, and D25 can be set as illustrated in the figure. Here, D15 is the shortest distance between the n⁺ layer 12 and the n layer 81A on the element T1 side, and D25 is the shortest distance between the n⁺ layer 12 and the n layer 81B on the element T2 side.

In this case, where D11⇄D21, by setting D15>D25, the element T2 can be broken down before the element T1, similar to the above.

Next, the planar structure of the field plate 30 in FIG. 2 and FIG. 3 will be specifically described. FIG. 7A is a view in which the planar structure of each field plate 30 is added to a plan view similar to FIG. 4, and the drain electrode 21 is added instead of the n⁺ layer 12, and FIG. 7B is an enlarged view of only the portion related to the three innermost field plates 30. As described above, the field plate 30 has basically the same structure as that described in, for example, Japanese Patent No. 3275964. Therefore, multiple field plates 30 formed as concentric rings centered on the drain electrode (common electrode) 21 are arranged and separated from each other in the radial direction.

As described above, in the breakdown voltage securing region (region where multiple field plates 30 are arranged), the potential on the high potential side (inner side) and the potential on the low potential side (outer side) are distributed in the radial direction by capacitive coupling between adjacent field plates 30. At this time, the potential on the high potential side (potential of the drain electrode 21) is applied to the innermost field plate 30. Therefore, in FIG. 2 and FIG. 3, the innermost (left side) field plate 30 overlaps with the upper portion of the interlayer insulating layer 20 of the drain electrode 21 in plan view, and is connected to the drain electrode 21 by a via wiring 21A penetrating through the interlayer insulating layer 20. This field plate 30 is capacitively coupled by being adjacent in the horizontal direction to the field plate 20 adjacent on the right side. Furthermore, the field plates 30 on the further right side (low potential side) are all the same.

However, the potential of the innermost field plate 30 can be determined in the same manner even in the case where the via wiring 21A is not provided and the drain electrode 21 and the innermost field plate 30 are insulated by the interlayer insulating layer 20, or even in the case where these are capacitively coupled similar to between the field plates 30. In FIG. 2, FIG. 3, and FIG. 7A and FIG. 7B, the drain electrode 21 and the innermost field plate 30 overlap in plan view, but in this case, it is not necessary for these to overlap in plan view, and for example, the innermost field plate 30 may be formed outside the drain electrode 21 in close proximity for these to be capacitively coupled. That is, the positional relationship and connection between the innermost field plate and the drain electrode can be appropriately set according to the configuration of the electrode and field plate. In both FIG. 2 (switching element region R1) and FIG. 3 (protection element region R2), the leftmost field plate 30 and the drain electrode 21 are connected, but it is clear that this connection may be performed in only one of the switching region R1 and the element region R2.

As shown in FIG. 7B, the field plates 30 other than the three on the outer side (low potential side) are concentric rings, and are continuously formed across the switching element region R1, the protection element region R2, and the connection region R3 therebetween.

The application of potential to the outermost (low potential side) field plate 30 can also be performed in the same manner as for the high potential side, as shown in FIG. 3. Here, the outermost (right side) field plate 30 is connected to the cathode electrode 26 that overlaps in plan view through a via wiring 26A. On the other hand, in FIG. 2, the gate electrode 25 is extended to the high potential side (left side) and faces the n layer 11 via an oxide film thicker than the gate oxide film 24, and this portion substantially becomes the field plate 30. These structures can also be appropriately set in the same manner as the high potential side.

However, the potential of the rightmost field plate 30 in FIG. 2 (switching element region R1) is VG, and the potential of the rightmost field plate 30 in FIG. 3 (protection element region R2) is VAN. Although both are low potentials, generally VG≠VAN. Therefore, the outer three field plates 30 in FIG. 7A are formed as divided field plate 30A in the switching element region R1 and field plate 30B in the protection element region R2. Accordingly, in the switching element region R1, VD and VG are appropriately distributed in the radial direction using the field plate 30A and the field plate 30 on the inner side thereof to adjust the surface potential of the n layer 11, and in the protection element region R2, VD and VAN are appropriately distributed in the radial direction using the field plate 30B and the field plate 30 on the inner side thereof to adjust the surface potential of the n layer 11. In the connection region R3, the field plate 30A and the field plate 30B are separated, so the influence of the potential difference in the circumferential direction in this portion is also small. Although the divided field plates 30 are on the outermost peripheral side, the number thereof is not necessarily three. In addition, although the field plates 30 are not disposed on the connection region R3 in FIG. 7A and FIG. 7B, the field plates 30 may also be disposed on the connection region R3.

With the above configuration, this field plate 30 can function in the same manner as described in, for example, Japanese Patent No. 3275964, and the breakdown voltage in the breakdown voltage securing region of this semiconductor device 1 can be enhanced.

In FIG. 4, the p layer 13 and the player 16 are completely divided. That is, these are divided from the radially inner side (high potential side) to the radially outer side (low potential side) in the connection region R3. However, the operations in the element T1 and the element T2 are mainly performed on the radially inner side with respect to the p layer 13 and the p layer 16 in FIG. 4. Therefore, the p layer 13 and the p layer 16 may be divided only on the radially inner side (common contact region side), and these may be connected on the radially outer side.

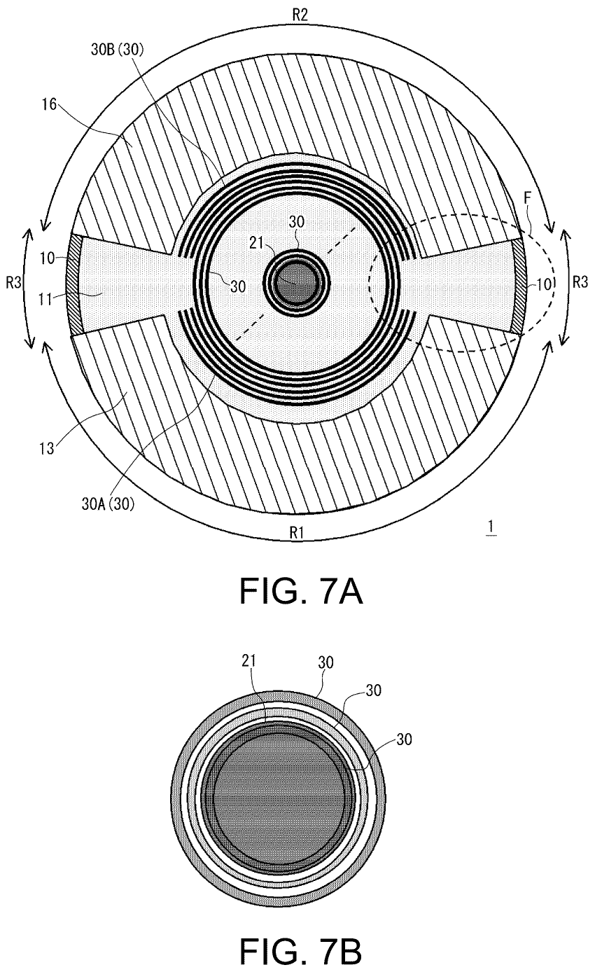

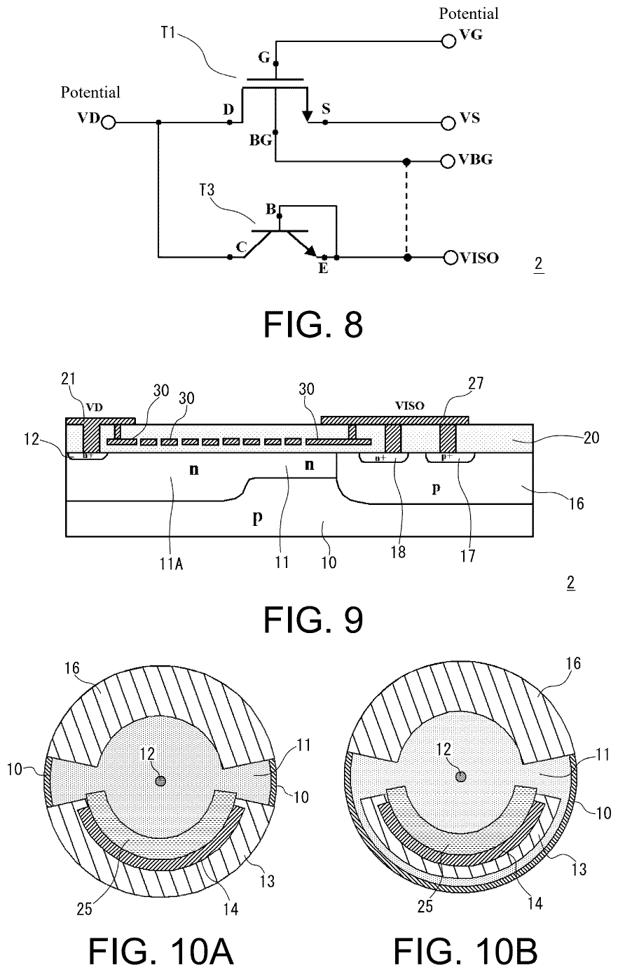

A modification example of the above semiconductor device 1 will be described. FIG. 8 is a circuit diagram corresponding to FIG. 1, showing the configuration of this semiconductor device 2. In this semiconductor device 2, an element T3 that is an npn transistor (bipolar transistor) is used as a protection element instead of the aforementioned element T2 that is a diode. Here, the collector (C: protection element side first electrode) of the element T3 is made common (potential VD) with the drain (D) of the element T1 instead of the aforementioned cathode (CA), and the potential of the emitter (E: protection element side second electrode) is set to VISO instead of the aforementioned anode (AN). VISO can be, for example, the potential of the outer peripheral portion of the element as described later. However, since the p-type layer serving as the base (B) and the n-type layer serving as the emitter (E) are actually short-circuited by wiring, the element T3 actually operates with two terminals. In the semiconductor device 2, the element T3 is normally in the off state, but in response to large external noise such as surge being mixed into VD, the element T3 can turn on to suppress surge from being applied to the element T1. This operation is similar to breakdown in parasitic transistor operation. The characteristics such as the on voltage of the element T3 can be finely adjusted by the spacing between the n⁺ layer 18 and the n layer 11, the impurity concentration of the p layer 16 and the n layer 11, VISO, etc., which will be described later.

FIG. 9 is a cross-sectional view on the element T3 side in this case, corresponding to FIG. 3. In this case, the player 16 and the p⁺ layer 17 are also formed similarly. Here, the p layer 16 functions as the base (B) layer of the element T3, and the p⁺ layer 17 is the contact layer. Here, an n⁺ layer (fifth semiconductor region) 18 whose potential is VISO is formed in the p layer 16, and the emitter electrode 27 connected to this n⁺ layer 18 is also connected to the p⁺ layer 17, thereby realizing the circuit configuration of FIG. 8.

In order to protect the element T1 with the element T3, it is preferable to set the element T3 to turn on before the element T1 or the circuits connected thereto are damaged. Such characteristics as the on voltage can be adjusted by setting the impurity concentration of the p layer 16. At this time, the point of making breakdown in the n layer 11 more likely to occur on the element T3 side than on the element T1 side while maintaining high breakdown voltage by setting the distances (D11, D21) between the n layer 11 and the players 13 and 16 and the distances (D12, D22) between the n layer 11A and the p layers 13 and 16 is effective, similarly to the case of the aforementioned semiconductor device 1. At this time, it is clear that the n layer 11 may have the same shape as in FIG. 5 and FIG. 6.

FIG. 10A and FIG. 10B are views showing two types of planar shapes in the case where the positional relationship between the p layer 13 and the p-type substrate 10 is changed in the semiconductor device 1 having the circuit configuration shown in FIG. 1. FIG. 10A is a view similar to FIG. 4, in which both the p layer 13 (potential VBG) and the p layer 16 (potential VAN) are connected to the p-type substrate 10 (VBG=VAN). In FIG. 10B, while the p layer 16 (VAN) is connected to the p-type substrate 10, the n layer 11 can be interposed to separate between the p layer 13 (VBG) and the p-type substrate 10.

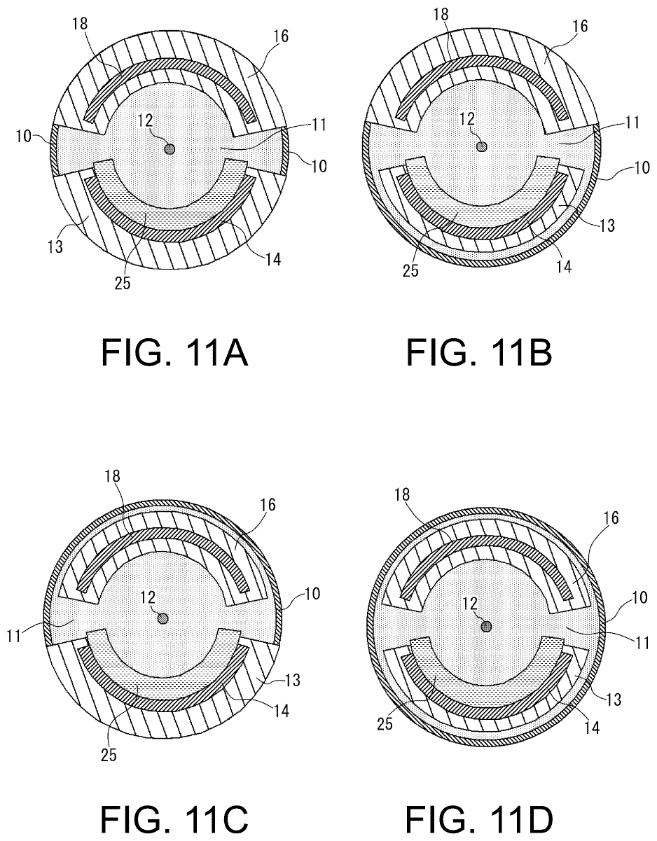

FIG. 11A to FIG. 11D are views showing planar shapes in the case where the positional relationship between the p layer 13 and the p-type substrate 10 is similarly changed in the semiconductor device 2 having the circuit configuration shown in FIG. 8. In FIG. 11A, both the p layer 13 (potential VBG) and the p layer 16 (potential VISO) are connected to the p-type substrate 10 (VBG=VISO). In FIG. 11B, while the p layer 16 (potential VISO) is connected to the p-type substrate 10, the player 13 (potential VBG) and the p-type substrate 10 can be separated similarly to FIG. 10B. In FIG. 11C, while the p layer 13 (potential VBG) is connected to the p-type substrate 10, the p layer 16 (potential VISO) can be separated from the p-type substrate 10. In FIG. 11D, both the p layer 13 (VBG) and the p layer 16 (VISO) can be separated from the p-type substrate 10.

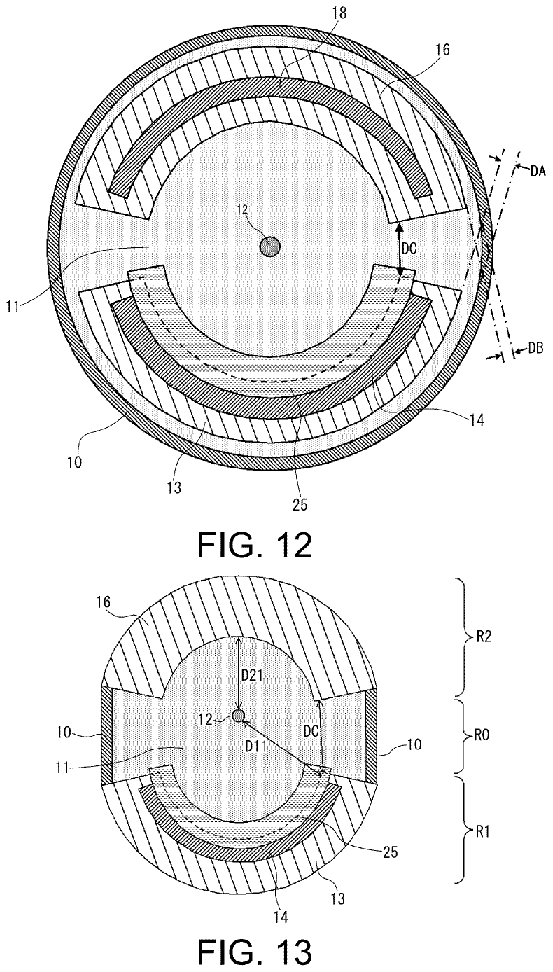

In FIG. 10A and FIG. 10B, and FIG. 11A to FIG. 11D, except for FIG. 10A and FIG. 11A, the potential difference between the p layer 13 and the p layer 16 (difference between VBG and VISO) differs according to the setting, so a breakdown voltage is required between the p layer 13 and the player 16. FIG. 12 is a plan view illustrating the structure of FIG. 11D from this viewpoint. Here, the spacing between the p-type substrate 10 and the p layer 13 is DA, the spacing between the p-type substrate 10 and the p layer 16 is DB, and the spacing between the p layer 13 and the p layer 16 is DC. Here, during operation of this semiconductor device, the potential of the p-type substrate 10 is, for example, GND and the potential VBG of the p layer 13 and the potential VISO of the p layer 16 are not limited to either positive or negative. Therefore, it is preferable to set the spacing DC between the p layer 13 and the p layer 16 so that spacing DC≥spacing DA and spacing DC≥spacing DB. Such requirements can be applied similarly to the semiconductor device 1 (FIG. 10A and FIG. 10B) of FIG. 1.

In order to both increase the breakdown voltage related to the switching element region R1 and the protection element region R2, and cause breakdown or turn-on on the elements T2 and T3 side in the protection element region R2 to occur earlier than on the element T1 side in the switching element region R1 as described above, it is preferable to adopt the structure having the planar shape as shown in FIG. 13. In FIG. 13, this semiconductor device 2 has a racetrack shape (a shape in which semicircular portions are separated vertically and connected by straight lines therebetween). A structure corresponding to FIG. 11A is shown here. In this structure, the connection region R3 sandwiched between the switching element region R1 and the protection element region R2 is secured to be longer than in the semiconductor device 2 of FIG. 11A, so as to separate the switching element region R1 and the protection element region R2 by a greater distance. In this case, it is easy to make the distance D11 between the p layer 13 and the n⁺ layer 12 greater than the distance D21 between the p layer 16 and the n⁺ layer 12. A similar structure can also be applied to the semiconductor device 1 (FIG. 10A and FIG. 10B).

Various planar structures that can be taken by each component in the semiconductor devices 1 and 2 have been shown above. In contrast thereto, in a semiconductor device 3 which is the second modification example described below, a new structure is particularly added on the surface. This semiconductor device 3 will be described hereinafter.

In a region F in FIG. 7A (the portion corresponding to the connection region R3 sandwiched between the p layer 13 and the p layer 16, where the p layer 13 and the p layer 16 are closely opposed to each other), depletion layers expand from the interface between the p layer 13 and the n layer 11, and from the interface between the p layer 16 and the n layer 11 during the off state of the semiconductor device 3. In the case where the depletion layers expanding from both sides come into contact with each other, conduction occurs between the p layer 13 and the p layer 16 (punch through occurs). Therefore, it is effective to widen the spacing between the p layer 13 and the p layer 16 (the length of the connection portion R3) as in the structure of FIG. 13, but the semiconductor device becomes larger in size.

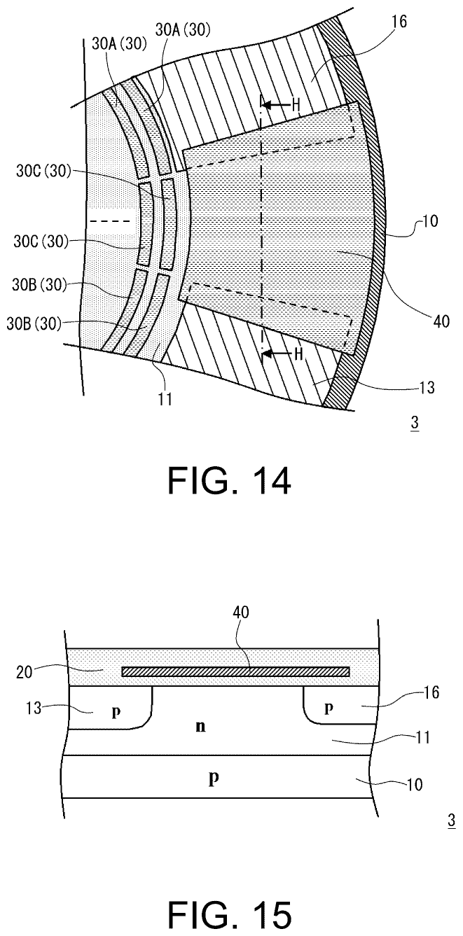

In order to suppress the occurrence of such punch through, it is preferable to provide an inter-element field plate 40 extending in the circumferential direction between the p layer 13 and the p layer 16 in the region F of FIG. 7A. FIG. 14 is a plan view showing the structure of such a semiconductor device 3, where only the portion corresponding to the region F in FIG. 7A and the peripheral area is shown.

In FIG. 14, the p-type substrate 10, the field plate 30 in FIG. 7A and FIG. 7B, the p layer 13, the p layer 16, and the inter-element field plate 40 are shown. In addition, FIG. 15 shows a cross section in the H-H direction in FIG. 14. In FIG. 15, the inter-element field plate 40, similar to the aforementioned field plate 30, faces the n layer 11 between the p layer 13 and the player 16 through the interlayer insulating layer 20 composed of a thick silicon oxide film.

As shown in FIG. 14, the inter-element field plate 40 is formed to extend so that one end overlaps with the p layer 13 in plan view and the other end overlaps with the p layer 16. Then, the inter-element field plate 40 is connected to the p layer 13 (potential VBG) or the p layer 16 (potential VISO). Thereby, in the n layer 11 between the p layer 13 and the p layer 16 directly below the inter-element field plate 40, extension of the depletion layer is suppressed, thereby preventing punch through.

Further, the inter-element field plate 40 may be connected to the gate electrode 25 (potential VG). In this case, the circumferential end of the gate electrode 25 in FIG. 4, etc. may extend in the circumferential direction to form a shape connected to the inter-element field plate 40.

Additionally, as shown in FIG. 7A, the field plate 30 on the outer side is divided into the field plate 30A in the switching element region R1 and the field plate 30B in the protection element region R2. However, in the case where the inter-element field plate 40 is provided, as shown in FIG. 14, a field plate 30C separated from the field plate 30A and the field plate 30B may be provided on the same circumference between the field plate 30A and the field plate 30B. The field plate 30C may be capacitively coupled with the field plate 30 on the radially inner side and the inter-element field plate 40 on the radially outer side, respectively.

The planar shape of the inter-element field plate 40 includes at minimum the shape of the inter-element field plate 40 shown in FIG. 14, and can be appropriately set as long as the shape does not affect other electrodes (wiring), etc.

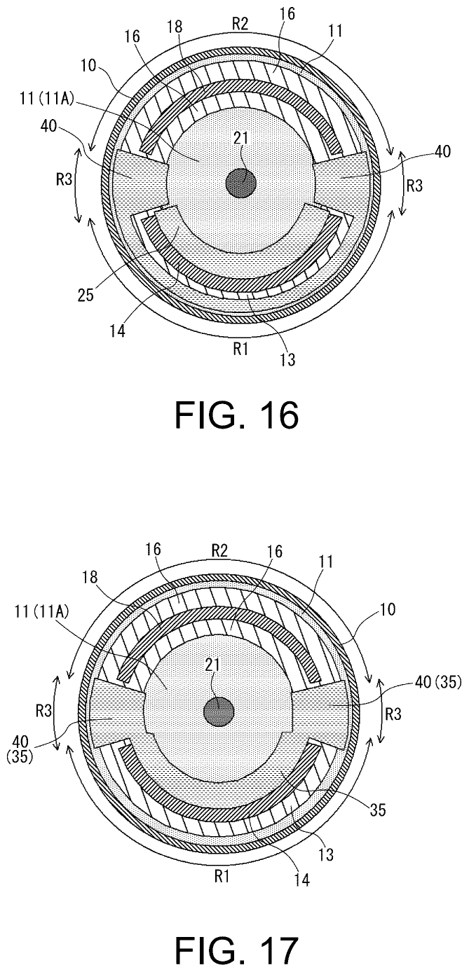

FIG. 16 shows an example of the overall planar shape in the case of connecting the inter-element field plate 40 to the p layer 13 side as described above. A field plate is also formed on the p layer 13 in the circumferential direction connecting the inter-element field plate 40. In this case, the electrical connection between the inter-element field plate 40 and the p layer 13 can be made on the p layer 13.

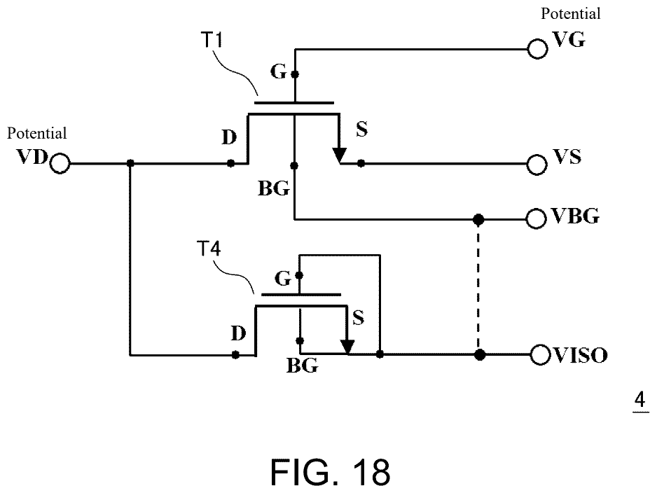

FIG. 17 shows an example of the overall planar shape in the case of integrating the inter-element field plate 40 with the gate electrode 35 similarly provided along the circumferential direction as described above. In this case, this structure can be obtained simply by changing the pattern of the gate electrode 25 if the silicon oxide film directly below the portion serving as the inter-element field plate 40 is formed as a LOCOS oxide film thicker than the gate oxide film 24. The illustration of the field plate 30 is omitted in FIG. 16 and FIG. 17.

In the above semiconductor device, the portions constituting the switching element region R1 and the protection element region R2 are formed in shapes along an arc shape. However, these portions are not necessarily formed in shapes along an arc shape, and it is sufficient that these portions are formed in shapes along the circumferential direction of the center (common contact region). Additionally, although at this time, the angle subtending the switching element region and the angle subtending the protection element region (spread in the circumferential direction) as viewed from the center are set equivalent in the above example, these angles are not necessarily set equivalent.

Furthermore, although multiple field plates 30 are used in the breakdown voltage securing region in the above example, it is not necessary to provide field plates in the breakdown voltage securing region in the case where the breakdown voltage can be secured without using such field plates. In this case, the structure of the semiconductor device becomes simpler and less expensive. Also, known resistive field plates or Shallow Trench Isolation may be used instead of the multiple field plates 30 in the breakdown voltage securing region. The same applies to the inter-element field plate 40.

Further, as the protection element, an n-channel type MOSFET (LDMOS) similar to the element T1 can be used instead of the npn transistor. FIG. 18 shows the configuration of a semiconductor device 4 as such a modification example (third modification example). An element (protection element) T4 used here is a MOSFET similar to the element T1, and the source (S), gate (G), and back gate (BG) are connected as illustrated. For example, in the case of making the interlayer insulating layer 20 directly below the rightmost field plate 30 in the figure connected to the emitter electrode 27 in FIG. 9 into a thinner gate oxide film 24 (FIG. 2), this field plate 30 can serve as the gate (G) of the element T4 in FIG. 18, and this can be connected to the p⁺ layer 17 and the n⁺ layer 18 by the emitter electrode 27, to easily realize this configuration. For other structures, the protection element T4 can be realized similarly by modifying the structure in the vicinity of the field plate.

Furthermore, in the plan views including FIG. 4, the portion serving as the element T1 and the portion serving as the element T2 (to T4) are both semicircular (the angle viewed from the center occupied by these arc shapes is 180°) and have the same area. However, these areas are not necessarily the same, and these areas may be appropriately set according to required element characteristics. For example, the area of the element T1 may be larger than the area of the element T2 (to T4). In this case, these areas can be changed by, for example, changing the aforementioned angle between the element T1 side and the element T2 side. In addition, in FIG. 4, etc., the portion serving as the element T1 and the portion serving as the element T2 are combined one by one in a single chip. However, in the case where the aforementioned angle in the portion serving as the element T1 and the portion serving as the element T2 in these planar structures is set smaller than 180°, there may be multiple combinations of these portions in the circumferential direction. In this case, the portion serving as the element T1 and the portion serving as the element T2 can also be alternately arranged in the circumferential direction.

Besides, other layers can be appropriately added to or deleted from the semiconductor layer. It is also clear that a similar configuration can be applied to the above example even in the case where all p-type and n-type in the semiconductor are reversed.

What is claimed is:

1. A semiconductor device, in which a switching element whose on/off is controlled by a potential of a control electrode between a first main electrode on a high potential side and a second main electrode on a low potential side, and a protection element that bypasses and flows a current between a protection element side first electrode on the high potential side and a protection element side second electrode on the low potential side during an off state of the switching element are formed on a semiconductor substrate, the semiconductor device comprising:
a first semiconductor region of a second conductivity type formed on a surface side of the semiconductor substrate of a first conductivity type, wherein the second conductivity type is opposite to the first conductivity type;
a common electrode serving as both the first main electrode and the protection element side first electrode; and
a common contact region of the second conductivity type formed locally with a high impurity concentration on the first semiconductor region and connected to the common electrode,
wherein one region and another region in a circumferential direction centered on the common contact region in plan view are respectively set as a switching element region where the switching element is formed and a protection element region where the protection element is formed,
the switching element region comprises a second semiconductor region of the first conductivity type and a third semiconductor region of the second conductivity type, wherein the second semiconductor region of the first conductivity type is locally formed at a location separated in a radial direction in the first semiconductor region from the common contact region in plan view, and the third semiconductor region of the second conductivity type is locally formed in the second semiconductor region in plan view,
the second main electrode is connected to the third semiconductor region,
the protection element region comprises a fourth semiconductor region of the first conductivity type, wherein the fourth semiconductor region of the first conductivity type is locally formed at a location separated in the radial direction in the first semiconductor region from the common contact region in plan view,
the protection element side second electrode is connected to the fourth semiconductor region, and
the first semiconductor region is integrated across the switching element region and the protection element region, and an end portion of the second semiconductor region on the common contact region side and an end portion of the fourth semiconductor region on the common contact region side are separated from each other in plan view.

2. The semiconductor device according to claim 1, wherein a shortest distance from the common contact region to the fourth semiconductor region in the protection element region is set shorter than a shortest distance from the common contact region to the second semiconductor region in the switching element region.

3. The semiconductor device according to claim 1, comprising a buried semiconductor region of the second conductivity type formed deeper than the first semiconductor region on the common contact region side in the semiconductor substrate and connected to the first semiconductor region,
wherein a shortest distance from the common contact region to the second semiconductor region and a shortest distance from the common contact region to the fourth semiconductor region are set equal, and a shortest distance from the buried semiconductor region to the second semiconductor region in the switching element region is set shorter than a shortest distance from the buried semiconductor region to the fourth semiconductor region in the protection element region.

4. The semiconductor device according to claim 1, wherein a plurality of field plates composed of conductors and facing a surface of the first semiconductor region through an insulating layer is formed to surround the common electrode in plan view so as to be capacitively coupled to each other between the common electrode and the control electrode, and between the common electrode and the protection element side second electrode.

5. The semiconductor device according to claim 1, comprising a fifth semiconductor region of the second conductivity type locally formed in the fourth semiconductor region,
wherein the protection element side second electrode is connected to the fifth semiconductor region.

6. The semiconductor device according to claim 5, wherein a shortest distance from the common contact region to the second semiconductor region in the switching element region and a shortest distance from the common contact region to the fourth semiconductor region in the protection element region are set equal.

7. The semiconductor device according to claim 1, wherein one of the second semiconductor region and the fourth semiconductor region is formed inside the first semiconductor region in plan view.

8. The semiconductor device according to claim 1, wherein one of the second semiconductor region and the fourth semiconductor region in plan view is connected to the semiconductor substrate on an outer side in the radial direction.

9. The semiconductor device according to claim 7, wherein the second semiconductor region is formed inside the first semiconductor region in plan view, and
a distance between an outermost periphery in the radial direction of a side that is not in direct contact with the semiconductor substrate other than a portion where the first semiconductor region is formed, and an outermost periphery in the radial direction of the first semiconductor region is set to a length equal to or less than a distance between the second semiconductor region and the fourth semiconductor region in the circumferential direction.

10. The semiconductor device according to claim 1, wherein an inter-element field plate composed of a conductor is formed on a surface of the first semiconductor region through an insulating layer, on the surface of the first semiconductor region between the second semiconductor region and the fourth semiconductor region where the second semiconductor region and the fourth semiconductor region are locally separated in the circumferential direction in plan view.

11. The semiconductor device according to claim 10, wherein the inter-element field plate is connected to the second semiconductor region, the fourth semiconductor region, or the control electrode by a conductive material.
